(19) United States
(12) Patent Application Publication
(10) Pub. No.: US 2013/0069091 A1
(43) Pub. Date: Mar. 21, 2013

(54) PROGRESSIVE-REFRACTIVITY ANTIREFLECTION LAYER AND METHOD FOR FABRICATING THE SAME

(71) Applicant: JIN SHIAN WANG, TORRANCE, CA (US)

(72) Inventor: JIN SHIAN WANG, TORRANCE, CA (US)

(73) Assignee: TAIWAN MICROPAQ CORPORATION, HSINCHU COUNTY (TW)

(21) Appl. No.: 13/236,939

(22) Filed: Sep. 20, 2011

(51) Int. Cl. H01L 33/58; B32B 37/16; C23C 16/50; B32B 37/12; G02B 1/11; C23C 16/40

(52) U.S. Cl. 257/98; 438/27; 359/586; 359/585; 427/569; 156/60; 257/E33.06

(57) ABSTRACT

The present invention discloses a progressive-refractivity antireflection layer and a method for fabricating the same to eliminate light reflection occurring in an interface. The present invention is characterized in being fabricated via depositing a first material and a second material, and having a refractivity (n_{eff}) gradually varying with a thickness thereof and ranging between a refractivity (n₁) of the first material and a refractivity (n₂) of the second material. No matter at what thickness the refractivity (n_{eff}) of the antireflection layer is measured, the refractivity (n_{eff}) meets an effective medium theory expressed by an equation: n_{eff}={n₁²f+n₂²(1−f)}^{1/2}, wherein f is a filling ratio of the first material of the antireflection layer.

### BACKGROUND OF THE INVENTION

1. Field of the Invention

The present invention relates to an antireflection layer and a method for fabricating the same, particularly to a progressive-refractivity antireflection layer and a method for fabricating the same.

2. Description of the Related Art

Recently, LED (Light Emitting Diode) has gradually replaced the incandescent lamp and the fluorescent lamp. As the blue light GaN (Gallium Nitride) LED features high brightness and high power, it has been extensively used as the material of white light LED. With advance of technology and science, the internal quantum efficiency of GaN material has reached as high as over 90%. However, the external quantum of LED is still below 10%. In other words, only a small portion of light emitted by LED is projected outsides. Most of the light is reflected back by the GaN interface to the interior thereof, heating the overall structure and causing light attenuation, which is the biggest drawback of LED.

The poor external quantum efficiency of LED is due to the big drop between air and semiconductor light emitting material. GaN has a blue light (with a wavelength of 440 nm) refractive index of 2.5, and air has a blue light refractive index of 1.0. From the Snell's Law, it is known that a light beam projecting from the interior of LED to air has a total reflection angle of 23.6 degrees. In other words, only the light inside the 23.6-degree cone is possible to leave the surface of LED. The light in the range of 23.6-90 degrees outside the cone is totally reflected back to the interior of LED. Constrained by the Fresnel Reflection effect of the surface of LED, a portion of the light inside the cone is also reflected back to the interior of LED, which further reduces the light output efficiency of the light inside the cone. The Fresnel Reflection effect is also due to the drop of the refractivities of air and GaN material. Therefore, the key to promote the light output efficiency of LED is to reduce or prevent from the light reflection caused by the refractivity difference between two sides of the interface.

For many years, an antireflection layer is coated on the surface of optical products, such as camera lenses, to decrease the Fresnel Reflection effect and improve light transmittance, which is called the Quarter Wavelength antireflection method, wherein a ¼-wavelength thick optical coating is applied on the surface of optical products to function as an antireflection layer. In the conventional technology, the refractive index n of the antireflection layer should be between the refractivities of GaN and air and satisfy an equation n=(n_{GaN}×nₐᵢᵣ)^{1/2}. The thickness d of the coating should meet an equation d=λ/4n, wherein λ is the wavelength of the incident light.

Recently, zinc oxide (ZnO) has been proposed to function as an antireflection material. ZnO has a refractive index of 2.0 and a special nanorod structure. Therefore, ZnO is very suitable to function as an antireflection material. There has been a successful case: the light extraction efficiency is increased by 15-20% via applying a single ZnO antireflection layer on the surface of LED to reduce the Fresnel Reflection effect. In the case, a first light beam is reflected from the GaN/ZnO interface, and a second light beam is reflected from the ZnO/air interface. As the thickness of the ZnO film is carefully calculated, the first light beam and the second light beam are out of phase, which results in destructive interference. Thus, there is no energy reflected. The ¼-wavelength antireflection method has a disadvantage: appropriate material is hard to obtain or fabricate. Besides, the thickness of the antireflection layer is closely related with the wavelength of light. The antireflection layer having a given thickness is only able to reflect light having a given wavelength but less effective or unlikely to reflect light having other wavelengths. Therefore, the ¼-wavelength antireflection method lacks an omnidirectional or broadband effect. A camera lens captures light coming from a source far away. However, the light source of LED is very close to the upper surface and emits light omnidirectionally. Thus, the ¼-wavelength antireflection layer fails to work for the light not vertically projected thereto.

Accordingly, the present invention proposes a novel progressive-refractivity antireflection layer and a method for fabricating the same to overcome the abovementioned problems.

### SUMMARY OF THE INVENTION

The primary objective of the present invention is to provide a progressive-refractivity antireflection layer and a method for fabricating the same so as to eliminate light reflection occurring in an interface.

Another objective of the present invention is to provide a progressive-refractivity antireflection layer and a method for fabricating the same so as to improve the light output efficiency of LED.

A further objective of the present invention is to provide a progressive-refractivity antireflection layer and a method for fabricating the same so as to reduce light reflected from the surface of solar cells, improve light transmittance and enhance the photoelectric effect.

To achieve the abovementioned objectives, the present invention proposes a progressive-refractivity antireflection layer characterized in that the antireflection layer is formed via depositing a first material and a second material and that the refractivity (n_{eff}) of the antireflection layer varies with the thickness thereof and ranges between the refractivity (n₁) of the first material and the refractivity (n₂) of the second material.

The present invention also proposes a method for fabricating a progressive-refractivity antireflection layer, which comprises steps: providing a vacuum chamber having a substrate, a first target and a second target thereinside, wherein the first target connects with a first cathode and a first programmable electric power source, and wherein the second target connects with a second cathode and a second programmable electric power source, and wherein the substrate connects with an anode; filling the vacuum chamber with argon and oxygen, and generating a plasma beam to bombard the first target and the second target; synchronously adjusting the first and second programmable electric power sources to regulate the powers for the first and second targets and modify the ratio of the plasma beams bombarding the first and second targets, whereby is deposited on the substrate an antireflection layer having refractivities gradually varying with the thickness thereof and ranging between the refractivities of the oxides of the first and second targets.

Below, embodiments are described in detail to make easily understood the objectives, technical contents, characteristics and accomplishments of the present invention.

### BRIEF DESCRIPTION OF THE DRAWINGS

FIG. 1(a) is a top view schematically showing an LED element used in the present invention;

FIG. 1(b) is a sectional view taken along Line A-A′ of FIG. 1(a) and schematically shows that the progressive-refractivity antireflection layer of the present invention is deposited on the LED element of FIG. 1(a);

FIG. 2 schematically shows that the refractivity of the progressive-refractivity antireflection layer varies with thickness;

FIG. 3 schematically shows the structure of a vacuum chamber used to fabricate a progressive-refractivity antireflection layer according to one embodiment of the present invention;

FIG. 4 shows a flowchart of a method to fabricate a progressive-refractivity antireflection layer according to one embodiment of the present invention;

FIG. 5 is a table showing the linear relationship of time and power, wherein the program controls the power of the zinc target to decrease continuously from 1 KW to zero within one hour, and wherein the program synchronously controls the power of the silicon target to increase continuously from zero to 1 KW; and

FIG. 6 shows ideal filling-ratio distribution curves of the first and second materials of the antireflection layer, wherein the first and second targets are respectively a zinc target and a P-type silicon target, and wherein the power for the first target is varied according to an equation {1−(10t³−15t⁴+6t⁵)} from high to low, and wherein the power for the second target is varied according to an equation (10t³−15t⁴+6t⁵) from low to high.

### DETAILED DESCRIPTION OF THE INVENTION

The present invention proposes a progressive-refractivity antireflection layer and a method for fabricating the same to eliminate reflection occurring in an interface. Applied to LED, the present invention can improve the light output efficiency. Applied to solar cells, the present invention can reduce light reflected from the surface of solar cells, improve light transmittance and enhance the photoelectric effect.

The present invention proposes a progressive-refractivity antireflection layer characterized in that the antireflection layer is formed via depositing a first material and a second material and that the refractivity (n_{eff}) of the antireflection layer varies with the thickness thereof and ranges between the refractivity (n₁) of the first material and the refractivity (n₂) of the second material, wherein the refractivity of the antireflection layer at each thickness meets the Effective Medium Theory n_{eff}={n₁²f+n₂²(1−f)}^{1/2}, and wherein f is the filling ratio of the first material of the antireflection layer.

Below are described the embodiments of applying the progressive-refractivity antireflection layer of the present invention to LED.

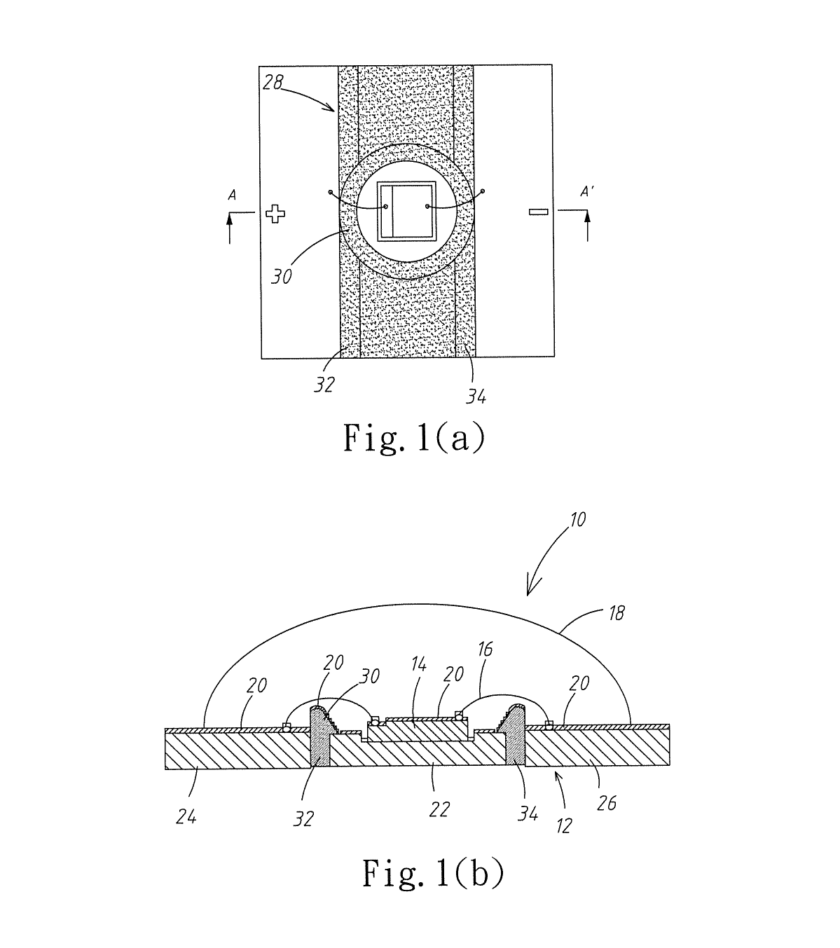

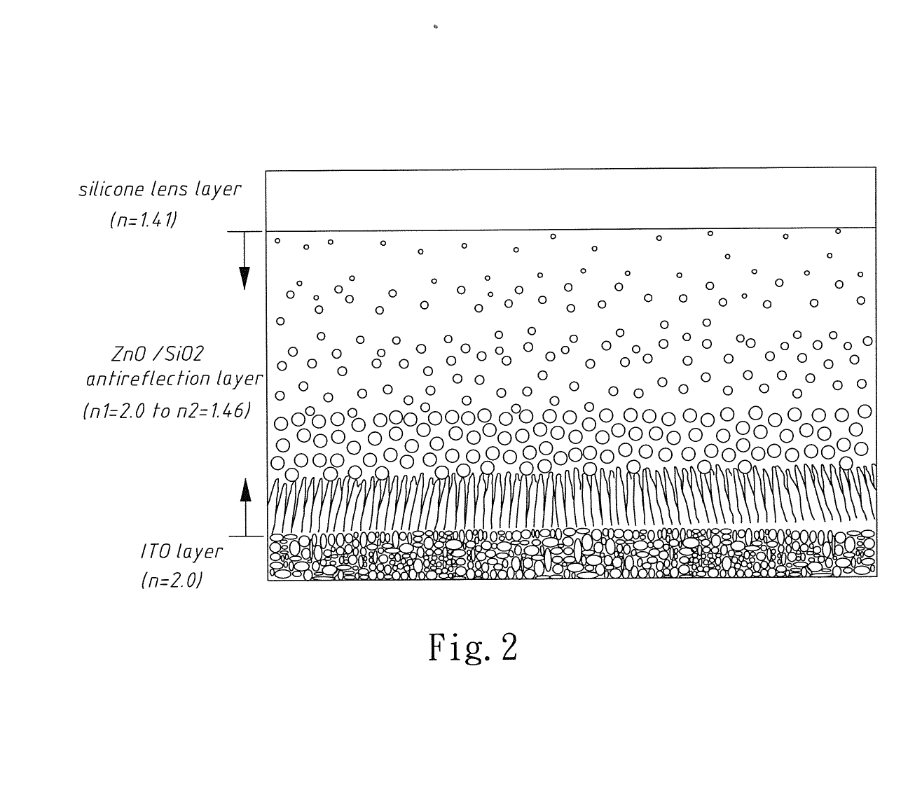

Refer to FIG. 1(a), FIG. 1(b) and FIG. 2. FIG. 1(a) is a top view schematically showing an LED element used in the present invention. FIG. 1(b) is a sectional view taken along Line A-A′ of FIG. 1(a) and schematically shows that the progressive-refractivity antireflection layer of the present invention is deposited on the LED element of FIG. 1(a). FIG. 2 schematically shows that the refractivity of the progressive-refractivity antireflection layer varies with thickness. The LED element 10 comprises a hybrid metallic lead frame 12, at least one LED chip 14, several wires 16, a silicone lens 18, and an antireflection layer 20.

The hybrid metallic lead frame 12 includes a chip-seat metallic lead frame 22, an anode metallic lead frame 24, a cathode metallic lead frame 26 and a forming resin 28.

The LED chip 14 is stuck to the chip-seat metallic lead frame 22. The anode metallic lead frame 24 and the cathode metallic lead frame 26 are respectively arranged in two sides of the chip-seat metallic lead frame 22.

The forming resin 28 is fabricated to form a reflective wall 30 annularly surrounding the LED chip 14, a first sidewall 32 and a second sidewall 34. The first side wall 32 is arranged between the chip-seat metallic lead frame 22 and the anode metallic lead frame 24 to join the chip-seat metallic lead frame 22 and the anode metallic lead frame 24. The second sidewall 34 is arranged between the chip-seat metallic lead frame 22 and the cathode metallic lead frame 26 to join the chip-seat metallic lead frame 22 and the cathode metallic lead frame 26.

The wires 16 electrically connect the LED chip 14 with the anode metallic lead frame 24 and the cathode metallic lead frame 26. The silicone lens 18 covers the LED chip 14 and the wires 16. The antireflection layer 20 of the present invention is deposited between the LED chip 14 and the silicone lens 18 to reduce light reflected by the interface and improve the light output efficiency.

When a transparent ITO (Indium Tin Oxide) conductive layer is formed on the LED chip 14, zinc oxide (ZnO) is used as the first material, and silicon dioxide (SiO₂) is used as the second material. Thus, the refractivity (n_{eff}) of the antireflection layer 20 gradually varies with the thickness thereof and ranges between the refractivity (n₁) of the first material and the refractivity (n₂) of the second material. The ratio of ZnO (n=2.0) and SiO₂ (n=1.46) is controlled to make the refractivity of the antireflection layer 20 gradually vary from n=2.0 (at the transparent ITO conductive layer on the surface of the LED chip 14) to n=1.41 (at the interface between the antireflection layer 20 and the silicone lens 18), whereby to reduce light reflected by the interface and increase the light output efficiency of LED.

In the case shown in FIG. 2, the refractivity of the antireflection layer 20 is divided into five levels (respectively represented by different patterns) according the thickness thereof. However, the present invention does not constrain that the antireflection layer 20 should be a five-level structure along the thickness thereof.

In a case that top layer of the LED chip 14 is made of an N-type GaN (n=2.5), the ITO layer is normally omitted, and the N-type GaN is directly used as the topmost layer of the LED chip 14. There is an obvious drop between the refractivity of the N-type GaN (n=2.5) and ZnO (n=2.0). Considering the obvious drop between the refractivities of the N-type GaN and ZnO, TiO₂ (n=2.7) (Titanium Dioxide) is used to replace ZnO, and a titanium target is used to replace the zinc target in the sputtering process. Thus, a TiO₂/SiO₂ antireflection layer is used in such a case.

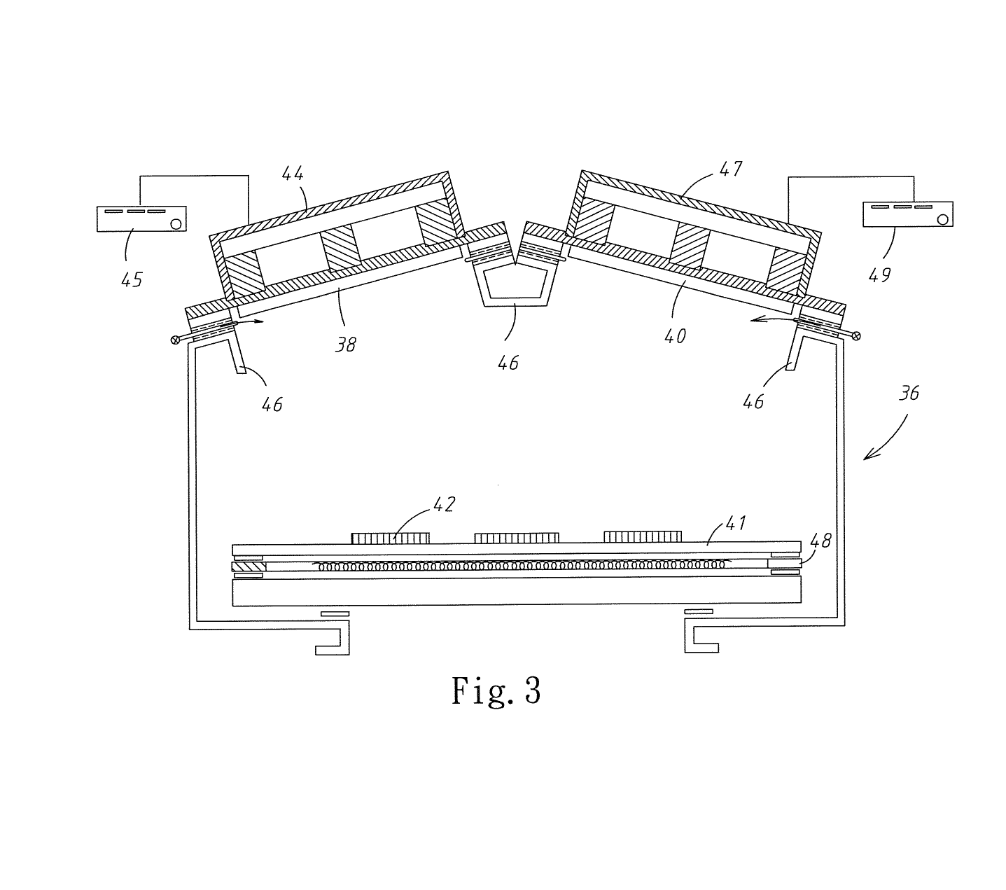

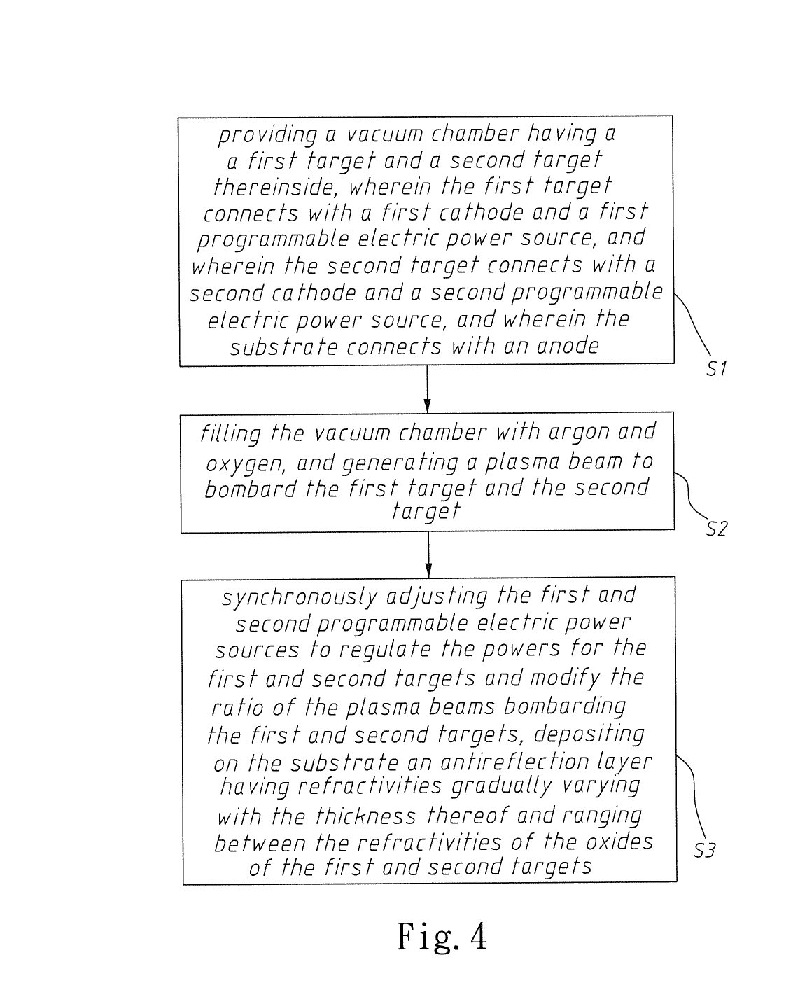

Refer to FIG. 3 and FIG. 4. FIG. 3 schematically shows the structure of a vacuum chamber used to fabricate a progressive-refractivity antireflection layer according to one embodiment of the present invention. FIG. 4 shows a flowchart of a method to fabricate a progressive-refractivity antireflection layer according to one embodiment of the present invention.

In Step S1, provide a vacuum chamber 36 (such as that shown in FIG. 3), wherein the vacuum chamber 36 has a first target 38, a second target 40, and several substrates 42 supported by a substrate platform 41, and wherein the first target 38 is connected with a first cathode 44 and a first programmable electric power source 45, and wherein the second target 40 is connected with a second cathode 47 and a second programmable electric power source 49, and wherein the substrates 42 are connected with an anode. In Step S2, fill argon and oxygen into the vacuum chamber 36 to generate plasma beams bombarding the first target 38 and the second target 40. In Step S3, synchronously adjust the first and second programmable electric power sources 45 and 49 to regulate the powers for the first and second targets 38 and 40 and modify the ratio of the plasma beams bombarding the first and second targets 38 and 40, and deposit on the substrates 42 an antireflection layer having a refractivity gradually varying with the thickness thereof and ranging between the refractivity (n₁) of the oxide of the first target and the refractivity (n₂) of the oxide of the second target.

As the first electric power source 45 and the second electric power source 49 are programmable, the powers applied to the first target 38 and the second target 40 can be adjusted according to requirement. For example, the first electric power source 45 and the second electric power source 49 can be varied linearly or according to an equation of a higher degree. In principle, the variation of the first electric power source 45 is complementary to that of the second electric power source 49. Preferably, the power for the first target 38 is varied according to an equation {1−(10t³−15t⁴+6t⁵)} from high to low, and the power for the second target 40 is varied according to an equation (10t³−15t⁴+6t⁵) from low to high, wherein t is the percentage of time.

The substrates 42 are the semi-products of LED, i.e. the LED element without a silicon lens. The hybrid metallic lead frame of the semi-product of LED is fabricated via pressing epoxy and a metallic lead frame at a high temperature and under a high pressure and able to endure a temperature of 200-300° C. in the sputtering process so as to obtain better adhesion of the antireflection layer.

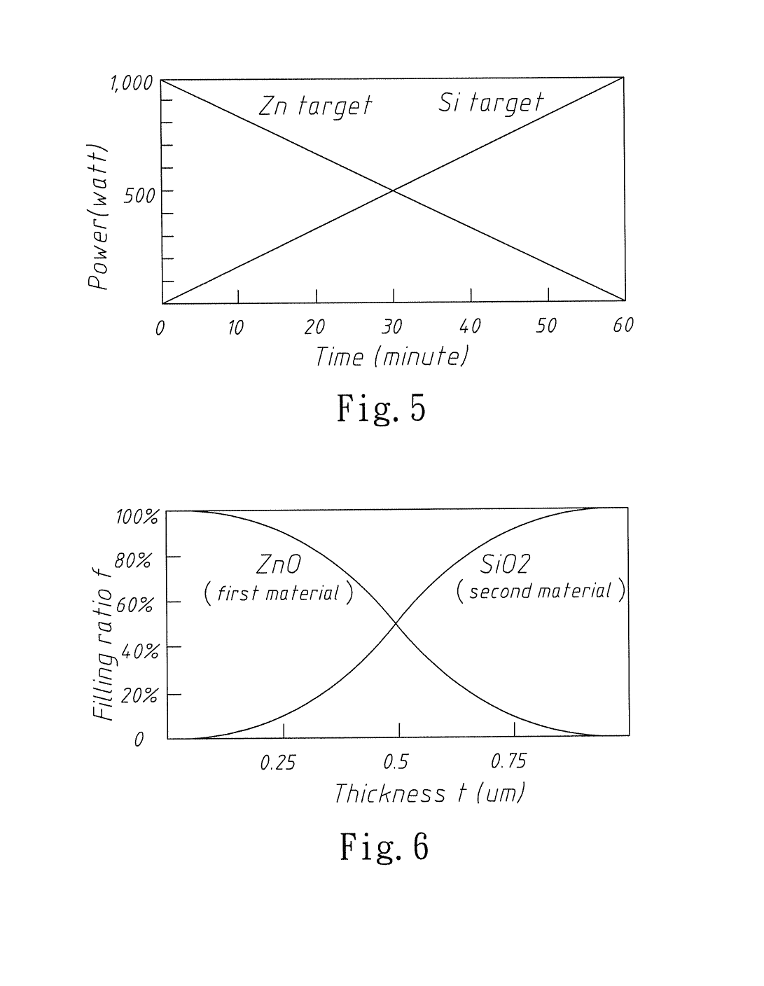

The present invention is characterized in synchronously using two programmable power supplies and adjusting the electric powers for the cathodes of the targets with time. The increment of time may be as small as 1 msec. Therefore, the variation of the electric powers can be regarded as continuous. Refer to FIG. 5. In a case, the first target is a zinc target, and the second target is a P-type silicon target. The program controls the power for the zinc target to decrease continuously from 1 KW to zero within one hour. At the same time, the program synchronously controls the power for the silicon target to increase continuously from zero to 1 KW. The growing speeds (nm/sec) of zinc oxide and silicon dioxide are respectively proportional to the power inputting to the targets. The greater the power, the higher the growing speed, and the higher the relative concentration.

In a case, the first target 38 is a zinc target, and the second target 40 is a P-type silicon target; each target is respectively connected with the cathode 44 of a 200 KHz pulsed DC power supply. The semi-products of LED are placed on the grounded anode. In practical operation, argon and oxygen mixed by a ratio of 4:6 is sprayed to the perimeter of the targets in the vacuum chamber to generate plasma bombarding the targets. The process generates ions or molecules of ZnO and SiO₂, which will descend on and then grow from the surface of the semi-products of LED. The ratio of gases can be varied to achieve better molecular structures. The cathodic targets are surrounded by shielding walls, which are appropriately grounded, to guarantee that the plasma under each target can stably work. The concentrations of ZnO and SiO₂ are respectively controlled by the powers (500-600V) inputting to the corresponding targets. In order to make ZnO and SiO₂ uniformly distributed on the surface of the semi-products of LED, the first target 38 and the second target 40 are respectively tilted leftward and rightward with respect to the central line of the vacuum chamber 36 by 10-15 degrees. The semi-products of LED may be heated with an infrared heater to a temperature of 200-300° C. to enhance the adhesion between the ZnO/SiO₂ particles and the surface of the semi-products of LED.

In the case that the first and second targets are respectively a zinc target and a P-type silicon target, the power for the first target is varied according to an equation {1−(10t³−15t⁴+6t⁵)} from high to low, and the power for the second target is varied according to an equation (10t³−15t⁴+6t⁵) from low to high, wherein t is the percentage of time. Thus are obtained ideal filling-ratio distribution curves of the first and second materials of the antireflection layer, as shown in FIG. 6. Thereby is also achieved an ideal refractivity curve. In such a case, the reflectivity is as low as 0.1%.

In the present invention, the antireflection layer is deposited at a timing that the wire-bonding process of the stuck LED chip has been completed but the transparent silicone lens has not been formed yet. Therefore, the present invention almost needn't vary the original fabrication process but only interposes a step of forming the antireflection layer into the original fabrication process. The antireflection layer of the present invention covers all the surface of the semi-product of LED. Besides, ZnO has a high thermal conductivity and thus can horizontally conduct the heat generated by LED to radiate outsides. The light output efficiency of LED can be increased at least 50% via sputtering the ZnO/SiO2 antireflection layer on the surface of the LED chip. The antireflection layer of the present invention is not limited to work at a specified wavelength but can apply to an extensive visible spectrum of 400-700 nm. Further, the antireflection layer of the present invention can be fabricated to have a broadband effect and apply to even the infrared light or the ultraviolet light.

The embodiments described above are only to exemplify the present invention but not to limit the scope of the present invention. Any equivalent modification or variation according to the spirit or characteristics of the present invention is to be also included within the scope of the present invention.

What is claimed is:

1. A progressive-refractivity antireflection layer, characterized in being fabricated via depositing a first material and a second material, and having a refractivity (n_{eff}) gradually varying with a thickness thereof and ranging between a refractivity (n₁) of said first material and a refractivity (n₂) of said second material.

2. The progressive-refractivity antireflection layer according to claim 1, wherein no matter at what thickness said refractivity (n_{eff}) of said antireflection layer is measured, said refractivity (n_{eff}) of said antireflection layer meets an effective medium theory expressed by an equation:
n_{eff}={n₁²f+n₂²(1−f)}^{1/2},
wherein f is a filling ratio of said first material of said antireflection layer.

3. The progressive-refractivity antireflection layer according to claim 1, which is deposited on a LED element or a solar cell.

4. The progressive-refractivity antireflection layer according to claim 3, wherein said LED element comprises:
a hybrid metallic lead frame including:
a chip-seat metallic lead frame where at least one LED chip is stuck;
an anode metallic lead frame and a cathode metallic lead frame respectively arranged on two sides of said chip-seat metallic lead frame; and
a forming resin containing:
a reflective wall annularly surrounding said LED chip;
a first sidewall arranged between said chip-seat metallic lead frame and said anode metallic lead frame and joining said chip-seat metallic lead frame and said anode metallic lead frame; and
a second sidewall arranged between said chip-seat metallic lead frame and said cathode metallic lead frame and joining said chip-seat metallic lead frame and said cathode metallic lead frame;
a plurality of wires electrically connecting said LED chip with said anode metallic lead frame and said cathode metallic lead frame; and
a silicone lens covering said LED chip and said wires, wherein said antireflection layer is arranged between said LED chip and said silicone lens.

5. The progressive-refractivity antireflection layer according to claim 4, wherein an ITO (Indium Tin Oxide) transparent conductive layer is formed on said LED chip, and wherein said first material comprises zinc oxide and said second material comprises silicon dioxide.

6. The progressive-refractivity antireflection layer according to claim 1, wherein an ITO (Indium Tin Oxide) transparent conductive layer is formed on said LED chip, and wherein said first material comprises zinc oxide and said second material comprises silicon dioxide.

7. The progressive-refractivity antireflection layer according to claim 4, wherein said first material is titanium dioxide and said second material is silicon dioxide.

8. The progressive-refractivity antireflection layer according to claim 1, wherein said first material is titanium dioxide and said second material is silicon dioxide.

9. A method for fabricating a progressive-refractivity antireflection layer, comprising steps:
providing a vacuum chamber, wherein said vacuum chamber has a first target, a second target, and a substrate, and wherein said first target is connected with a first cathode and a first programmable electric power source, and wherein said second target is connected with a second cathode and a second programmable electric power source, and wherein said substrate is connected with an anode;
filling argon and oxygen into said vacuum chamber to generate plasma beams bombarding said first target and said second target; and
synchronously adjusting said first programmable electric power source and said second programmable electric power source to regulate powers for said first target and said second target and modify a ratio of said plasma beams bombarding said first target and said second target, and depositing on said substrate an antireflection layer having a refractivity gradually varying with a thickness thereof and ranging between a refractivity (n₁) of an oxide of said first target and a refractivity (n₂) of an oxide of said second target.

10. The method for fabricating a progressive-refractivity antireflection layer according to claim 9, wherein power variation of said first target is complementary to that of said second target.

11. The method for fabricating a progressive-refractivity antireflection layer according to claim 9, wherein power for said first target is varied according to an equation {1−(10t³−15t⁴+6t⁵)} from high to low, and wherein power for said second target is varied according to an equation (10t³−15t⁴+6t⁵) from low to high, and wherein t is a percentage of time.

12. The method for fabricating a progressive-refractivity antireflection layer according to claim 9, wherein said substrate is a semi-product of a LED element.

13. The method for fabricating a progressive-refractivity antireflection layer according to claim 12, wherein said semi-product of said LED element comprises:
a hybrid metallic lead frame including:
a chip-seat metallic lead frame where at least one LED chip is stuck;
an anode metallic lead frame and a cathode metallic lead frame respectively arranged on two sides of said chip-seat metallic lead frame; and
a forming resin containing:
a reflective wall annularly surrounding said LED chip;
a first sidewall arranged between said chip-seat metallic lead frame and said anode metallic lead frame and joining said chip-seat metallic lead frame and said anode metallic lead frame; and
a second sidewall arranged between said chip-seat metallic lead frame and said cathode metallic lead frame and joining said chip-seat metallic lead frame and said cathode metallic lead frame;
a plurality of wires electrically connecting said LED chip with said anode metallic lead frame and said cathode metallic lead frame, wherein said antireflection layer is formed on said LED chip and said hybrid metallic lead frame.

14. The method for fabricating a progressive-refractivity antireflection layer according to claim 13 further comprising a step of forming a silicone lens over said semi-product to cover said LED chip, said antireflection layer and said wires after said antireflection layer has been deposited.

15. The method for fabricating a progressive-refractivity antireflection layer according to claim 9, wherein said first target comprises zinc and said second target comprises silicon.

16. The method for fabricating a progressive-refractivity antireflection layer according to claim 12, wherein said first target comprises zinc and said second target comprises silicon.

17. The method for fabricating a progressive-refractivity antireflection layer according to claim 9, wherein said first target comprises titanium and said second target comprises silicon.

18. The method for fabricating a progressive-refractivity antireflection layer according to claim 12, wherein said first target comprises titanium and said second target comprises silicon.

19. The method for fabricating a progressive-refractivity antireflection layer according to claim 9, wherein argon and oxygen is mixed by a ratio of 4:6.

20. The method for fabricating a progressive-refractivity antireflection layer according to claim 12, wherein argon and oxygen is mixed by a ratio of 4:6.

21. The method for fabricating a progressive-refractivity antireflection layer according to claim 9 further comprising a step of heating said substrate.

22. The method for fabricating a progressive-refractivity antireflection layer according to claim 12 further comprising a step of heating said substrate.
